(19) United States
(12) Patent Application Publication
(10) Pub. No.: US 2026/0198272 A1
(43) Pub. Date: Jul. 9, 2026

(54) METHOD OF MANUFACTURING A SILICON-ON-INSULATOR SUBSTRATE

(71) Applicant: STMicroelectronics International N.V., Geneva (CH)

(72) Inventors: Franck JULIEN, La Penne Sur Huveaune (FR); Arnaud REGNIER, Les Taillades (FR); Antonin CHOLLET, Rousset (FR); Stephane MONFRAY, Eybens (FR)

(73) Assignee: STMicroelectronics International N.V., Geneva (CH)

(21) Appl. No.: 19/401,187

(22) Filed: Nov. 25, 2025

(30) Foreign Application Priority Data
Dec. 5, 2024 (FR) FR2413517

(51) Int. Cl. H10P 90/00; H10D 86/00

(52) U.S. Cl. CPC H10P 90/1906; H10D 86/201

(57) ABSTRACT

The present description relates to a method of manufacturing a silicon-on-insulator substrate comprising the successive steps of: a) formation of a silicon-germanium layer on an upper surface of a silicon substrate; b) formation of a silicon layer on an upper surface of the silicon-germanium layer; c) formation of at least one opening crossing the silicon layer and emerging into the silicon-germanium layer; d) selective removal of at least part of the silicon-germanium layer through the opening to create a cavity between the silicon substrate and the silicon layer; and e) filling the cavity through the opening with an insulating material.

This application claims the priority benefit of French patent application number 2413517, filed on Dec. 5, 2024, entitled “Procédé de fabrication d'un substrat de type silicium sur isolant” which is hereby incorporated by reference to the maximum extent allowable by law.

### BACKGROUND

### Technical Field

The present disclosure relates generally to the field of silicon-on-insulator semiconductor substrates. More specifically, it covers a method or process for manufacturing such substrates.

### Description of the Related Art

Silicon-on-insulator (SOI) substrates consist of a multilayer structure comprising a layer of insulator between two layers of silicon.

Such substrates are particularly used for manufacturing electronic components, for example, to enhance their performance. However, these substrates are usually fabricated on whole semiconductor wafers and are often expensive.

It would be desirable to overcome some or all of the drawbacks of SOI substrates and their manufacturing methods.

### BRIEF SUMMARY

To this end, one embodiment provides a method of manufacturing a silicon-on-insulator substrate comprising the successive steps of:
a) formation of a silicon-germanium layer on a top surface of a silicon substrate;
b) formation of a silicon layer on an upper surface of the silicon-germanium layer;
c) formation of at least one opening, crossing the silicon layer and emerging into the silicon-germanium layer;
d) selective removal of at least part of the silicon-germanium layer through the opening to create a cavity between the silicon substrate and the silicon layer; and
e) filling the cavity, through the opening, with an insulating material.

In one embodiment, at the end of step e), the cavity is completely filled with the insulating material.

In one embodiment, at the end of step e), the cavity is partially filled with the insulating material.

In one embodiment, the silicon germanium layer is doped.

In one embodiment, in step a), the silicon-germanium layer is formed by epitaxy.

In one embodiment, in step b), the silicon layer is formed by epitaxy.

In one embodiment, when filling the cavity in step e), the at least one opening crossing the silicon layer is also filled with the insulating material.

According to one embodiment, the process comprises, prior to step a), a step of localized removal of part of the thickness of the silicon substrate, and, in step a), the silicon-germanium layer is formed only in a cavity formed by said localized removal of part of the thickness of the silicon substrate.

In one embodiment, in step d), the silicon-germanium layer is completely or partially removed.

According to one embodiment, the process comprises, between steps a) and b), a step of forming a silicon encapsulation layer on the upper face of the silicon-germanium layer.

According to one embodiment, in step a), the silicon-germanium layer is formed over the entire surface of the silicon substrate.

According to one embodiment, in step b), the silicon layer is formed over the entire surface of the silicon-germanium layer and is formed in contact therewith.

According to one embodiment, the process comprises, prior to step a), a step of forming a dielectric layer on a portion of the substrate, the silicon-germanium layer being formed only outside the facing of the dielectric layer.

In another embodiment, a process is provided for manufacturing an electronic chip in and on a silicon-on-insulator substrate obtained by a process described above, comprising a step of forming a transistor in and on the silicon layer.

Yet another embodiment provides a silicon-on-insulator substrate comprising, in a first region:
a layer of insulating material on an upper surface of a silicon substrate; and
a silicon layer on an upper face of the layer of insulating material,
the silicon layer having at least one opening therethrough.

In one embodiment, said at least one opening through the silicon layer is filled with said insulating material.

In one embodiment, in at least one second region, the silicon layer lies directly on and in contact with the silicon substrate.

In one embodiment, the lower surface of the silicon layer in the second region is aligned with the lower surface of the layer of insulating material in the first region.

In one embodiment, in at least one second region, the silicon layer is separated from the silicon substrate by a silicon-germanium layer.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1, FIG. 2, FIG. 3, FIG. 4, FIG. 5, FIG. 6, FIG. 7A, FIG. 7B, FIG. 8, FIG. 9A, FIG. 9B, FIG. 9C, FIG. 10 and FIG. 11 are cross-sectional or top views of structures obtained at the end of successive steps of a process for manufacturing a substrate, of the silicon-on-insulator type, according to a first embodiment;

FIG. 12, FIG. 13, FIG. 14, FIG. 15, FIG. 16, FIG. 17 and FIG. 18 are cross-sectional views of structures obtained in successive steps of a process for manufacturing a substrate, of the silicon-on-insulator type, according to a second embodiment;

FIG. 19, FIG. 20, FIG. 21, FIG. 22, FIG. 23, FIG. 24 and FIG. 25 are cross-sectional views of structures obtained at the end of successive steps of a process for manufacturing a substrate, of the silicon-on-insulator type, according to a third embodiment; and

FIG. 26A, FIG. 26B, FIG. 26C and FIG. 26D are top views illustrating different versions of the structure shown in FIG. 7A.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures, or to a . . . as orientated during normal use.

Unless specified otherwise, the expressions “around,” “approximately,” “substantially” and “in the order of” signify within 10% or 10°, and preferably within 5% or 5°.

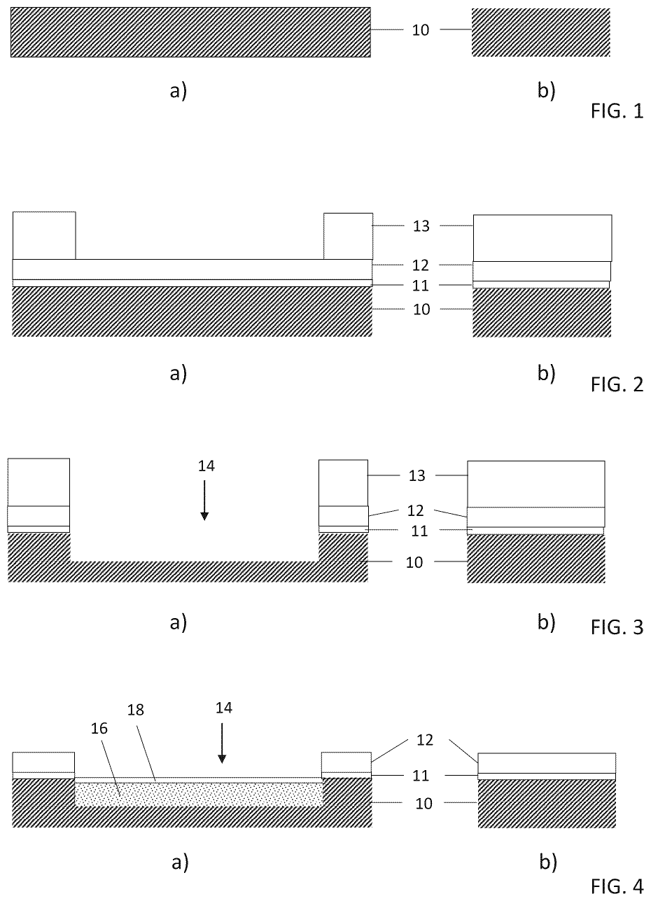

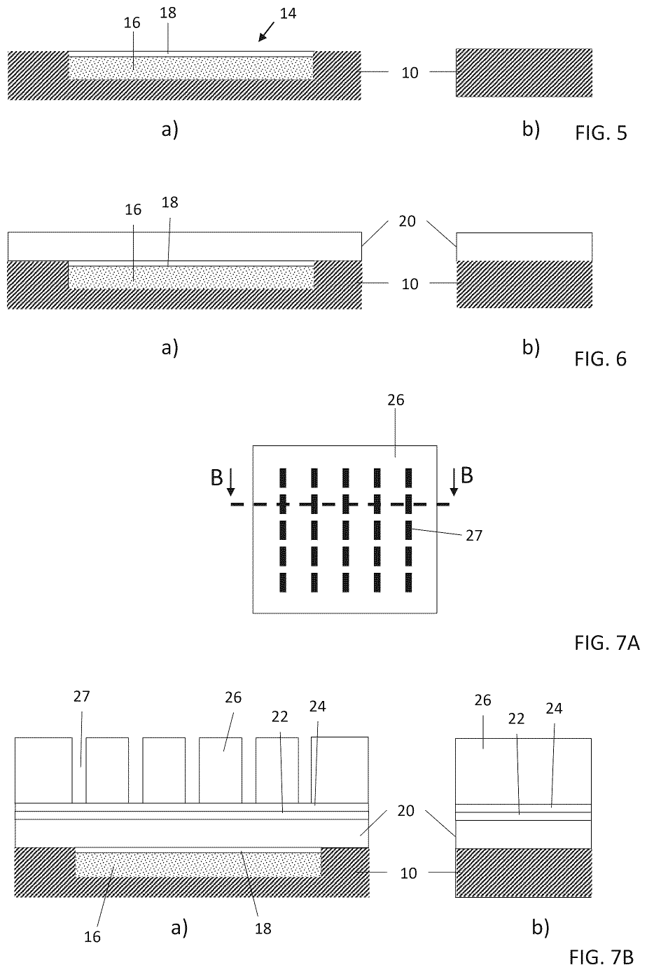

FIG. 1, FIG. 2, FIG. 3, FIG. 4, FIG. 5, FIG. 6, FIG. 7A, FIG. 7B, FIG. 8, FIG. 9A, FIG. 9B, FIG. 9C, FIG. 10 and FIG. 11 are cross-sectional or top views of structures obtained at the end of successive steps of an example of a process for manufacturing a substrate, of the silicon-on-insulator type, according to a first embodiment.

FIG. 1 illustrates a starting structure comprising a silicon substrate 10. The silicon substrate 10 is, for example, a silicon wafer. Substrate 10 is, for example, a crystalline substrate. By way of example, substrate 10 has a thickness in the range 300 μm to 1 mm, for example 500 μm to 800 μm, substrate 10 having a thickness of the order of 775 μm, for example.

By way of example, substrate 10 comprises a first region a) in which substrate 10 will, in the course of the process described below, be transformed into a Silicon On Insulator (SOI) substrate. For example, substrate 10 comprises a second region b) in which the substrate is not transformed and remains a silicon substrate.

For example, within a single wafer 10, a plurality of parts a) and parts b) are formed. For example, parts a) and b) are arranged in a matrix in which parts a) and b) alternate.

Alternatively, the substrate 10 comprises a single part a) and a single part b), for example adjacent to each other. For example, part a) corresponds to a central part of substrate 10 and part b) corresponds to a peripheral part of substrate 10.

FIG. 2 is a schematic partial cross-sectional view of a structure obtained after a step of depositing masking layers 11, 12 and 13 on, and for example in contact with, the top face of the starting structure illustrated in FIG. 1

More particularly, during this step, layer 11 is formed on the top face of substrate 10, and is in contact with it, for example. By way of example, layer 11 is formed over the entire top surface of substrate 10. Layer 11 is for example made of a dielectric material, for example silicon oxide. Layer 11 has, for example, a thickness in the range from 1 nm to 10 nm, for example, layer 11 has a thickness of around 8 nm.

By way of example, layer 12 is formed on the upper face of layer 11 and is for example in contact with it. By way of example, layer 12 is formed over the entire top surface of layer 11. Layer 12 is for example made of a dielectric material, for example silicon nitride. Layer 12 has, for example, a thickness in the range from 1 nm to 200 nm, for example, layer 12 has a thickness of around 110 nm.

Alternatively, the stack of layers 11 and 12 is made of silicon nitride, silicon oxide, or corresponds to a stack of silicon oxide, silicon nitride and silicon oxide called ONO. FIG. 3 is a partial schematic cross-sectional view of a structure obtained by removing the masking layers 11 and 12 and part of the thickness of the substrate 10 to form a cavity 14 in the layers 11, 12 and in the substrate 10.

For example, in this step, only the parts of layers 11 and 12 not covered by layer 13 are completely removed. For example, in this step, the parts of substrate 10 not covered by layer 13 are partially removed, i.e., only part of the thickness of substrate 10 is removed. The etching process used in this step is, for example, a plasma etching process based on hydrogen bromide and dioxygen or carbon tetrafluoride and dioxygen, or a chemical vapor etching process, for example based on hydrochloric acid. Alternatively, the process implemented in this step comprises consumption of silicon by an oxidation process to consume the desired thickness of silicon, followed by selective etching to remove the oxidized silicon.

The thickness of cavity 14 is, for example, in the range from 10 nm to 500 nm, for example in the range from 25 nm to 250 nm, for example in the range from 50 nm to 120 nm.

FIG. 4 is a schematic partial cross-sectional view of a structure obtained by forming a silicon-germanium layer 16 and a silicon layer 18 in the cavity 14 of FIG. 3

For example, in a first step, the silicon-germanium layer 16 is formed in the cavity 14 on and, for example, in contact with the substrate 10. By way of example, the silicon-germanium layer 16 is formed by epitaxy. For example, silicon-germanium layer 16 is formed by selective epitaxy localized outside the opposite side of layer 12. Thus, layer 16 is formed in cavities 14 only and is not formed on layer 12.

By way of example, the silicon-germanium layer 16 comprises a percentage of germanium in the range from 20% to 40%, for example a percentage of the order of 30% in atomic concentration

For example, the silicon-germanium layer 16 is thinner than the depth of cavity 14. For example, the silicon-germanium layer 16 has a thickness in the range from 10 nm to 150 nm.

By way of example, at the end of this step, the silicon-germanium layer 16 is in contact with the lower surface and the flanks or sides of cavity 14.

By way of example, in a second step, the silicon layer 18 is formed on, and for example in contact with, the silicon-germanium layer 16. For example, layer 18 is formed by epitaxy. For example, layer 18 is formed by selective epitaxy. Thus, layer 18 is not formed on layer 12.

For example, silicon layer 18 encapsulates silicon-germanium layer 16 in cavity 14. Once the silicon layer 18 has been formed, the silicon-germanium layer 16 is covered by the silicon layer 18 on the top and by the substrate 10 on the bottom and sides. The total encapsulation of the silicon-germanium layer 16 limits its exposure to air or to the controlled environment of deposition or etching equipment, which can cause its degradation.

By way of example, silicon layer 18 has a thickness enabling the top face of layer 18 to be flush with the top face of the parts of substrate 10 covered by layer 12. For example, layer 18 has a thickness in the range from 5 nm to 20 nm.

At the end of this stage, the substrate, layer 16 and layer 18 together form a continuous crystalline phase, for example without any break in the crystalline phase between the individual layers.

By way of example, layers 16 and 18 are doped in order to modify their properties, for example their conductivity properties. For example, layers 16 and 18 are doped with boron, arsenic, carbon, phosphorus or tin atoms, or any other atoms such as electron donors or acceptors.

Although an embodiment has been described here in which layer 16 is covered by layer 18, layer 18 is optional. A variant in which layer 18 is omitted is also possible.

FIG. 5 is a schematic partial cross-sectional view of a structure obtained by removing layers 11 and 12.

By way of example, this step is carried out by wet etching, for example with phosphoric acid (H₃PO₄) or hydrofluoric acid (HF).

At the end of this stage, the upper surface of the structure is flat and made of silicon, for example.

FIG. 6 is a schematic partial cross-sectional view of a structure obtained after the step of forming a silicon layer 20 on the top face of the structure illustrated in FIG. 5.

For example, in this step, layer 20 is formed as a full sheet on the top face of the structure shown in FIG. 5. By way of example, silicon layer 20 is formed by epitaxy. The epitaxy used to form layer 20 is non-selective, i.e., non-localized. In this way, layer 20 is formed simultaneously on the upper surface of layer 18 and on the upper surface of substrate 10.

Layer 20 is, for example, a monocrystalline silicon layer. Layer 20 is for example doped with atoms of boron, arsenic, carbon, phosphorus or any other atoms of the electron-donor or electron-acceptor type.

Layer 20 has, for example, a thickness in the range 15 nm to 250 nm, for example a thickness in the range 60 nm to 80 nm, for example a thickness of the order of 70 nm.

FIG. 7A and FIG. 7B are schematic partial top and cross-sectional views, respectively, of a structure obtained after a step of forming a hard mask and a layer of a resin 26 on the upper face of the structure illustrated in FIG. 6. FIG. 7B is a cross-sectional view of the structure along a sectional plane BB of FIG. 7A.

By way of example, the hard mask comprises a dielectric layer 22 and an insulating layer 24.

During this step, the insulating layer 22 is first formed on the upper surface of layer 20. The dielectric layer 22 is, for example, formed in full sheet so as to completely cover the surface of the silicon layer 20. By way of example, layer 22 is formed in contact with layer 20. Layer 22 is made of an insulating material, e.g., an oxide, e.g., silicon oxide, e.g., tetraethyl orthosilicate (TEOS).

Layer 22 has for example a thickness in the range from 5 nm to 25 nm, for example, a thickness of around 8 nm

In a second step, the other insulating layer 24 is formed on the upper surface of layer 22. The insulating layer 24 is, for example, formed as a full sheet so as to completely cover the surface of the insulating layer 22. By way of example, layer 24 is formed in contact with layer 22. Layer 24 is made of an insulating material, such as a nitride, e.g., silicon nitride.

Layer 24 has, for example, a thickness in the range from 30 nm to 250 nm, for example, a thickness of around 120 nm.

In a third step, a resin layer 26 is formed on the upper surface of layer 24. The resin layer 26 is, for example, formed as a full sheet so as to completely cover the surface of the insulating layer 24. By way of example, layer 26 is formed in contact with layer 24. Layer 26 is for example made of a photosensitive resin, for example a positive resin.

Layer 26 is, for example, 10 nm to 500 nm thick.

Once deposited, layer 26 is photolithographically exposed, for example, to form patterns 27. More specifically, during this step, portions of the resin layer 26 are locally removed to reveal the upper face of layer 24.

By way of example, as shown in FIG. 7A, patterns 27 in resin layer 26 correspond to parallel dotted lines.

By way of example, in order to ensure the mechanical stability of the structure in the successive steps, and in particular during a step of removal of the silicon-germanium layer 16, illustrated in relation to FIGS. 9A, 9B and 9C, the patterns 27 are formed in such a way that the layer 26 comprises only portions that are mechanically integral with one another. In other words, in this step, the patterns 27 in the resin layer 26 do not isolate a portion of the resin layer 26.

FIG. 8 is a schematic partial cross-sectional view of a structure obtained after a step of etching the structure illustrated in FIGS. 7A and 7B by creating openings 28 passing through the structure and extending into all or part of the silicon-germanium layer 16 and a step of removing the resin layer 26 from the top face of the obtained structure.

For example, in this step, openings 28 are created by etching.

The openings 28 pass through the silicon layer 20 and into the silicon-germanium layer 16. By way of example, the openings 28 also pass through the insulating layers 22 and 24. In the embodiment shown in FIG. 8, the openings 28 also pass through the silicon layer 18.

Alternatively, the openings 28 pass through the silicon layer 20 and the silicon-germanium layer 16 into the substrate 10. For example, openings 28 also pass through insulating layers 22 and 24.

By way of example, the openings 28 have a width in the range 100 nm to 500 nm

At the end of the openings-forming step 28, the resin layer 26 is removed to reveal the top face of the insulating layer 24.

FIG. 9A and FIGS. 9B and 9C are schematic partial top views and cross-sections, respectively, of a structure obtained by removing the silicon-germanium layer 16 through the openings 28 in the structure illustrated in FIG. 8, to create a cavity 30 between the substrate 10 and the silicon layer 20. FIG. 9B is a cross-sectional view of the structure along a sectional plane BB of FIG. 9A, and FIG. 9C is a cross-sectional view of the structure along a sectional plane CC of FIG. 9A.

More particularly, in this step, the silicon-germanium layer 16 is selectively removed, i.e., only the silicon-germanium layer 16 is removed in this step.

For example, the silicon-germanium layer 16 is etched away using a gaseous hydrochloric acid (HCl) solution.

Alternatively, the silicon-germanium layer 16 is removed by dry etching using a plasma based on tetrafluoromethane (CF₄), oxygen (O2) and helium (He).

Alternatively, the silicon-germanium layer 16 is removed by wet etching with fluoridic acid (HF).

At the end of this step, the structure no longer contains a silicon-germanium layer 16. By way of example, at the end of this step, cavity 30 is filled with air or a gas, for example the gas present in the atmosphere of the etching chamber.

FIG. 10 is a schematic partial cross-sectional view of a structure obtained by filling the cavity 30 of the structure illustrated in FIGS. 9A to 9C with a layer 32 through the openings 28.

In particular, during this step, the cavity 30 is filled with the material of layer 32 from the top face of the structure shown in FIGS. 9A, 9B and 9C.

Layer 32 is made of an insulating material, for example an oxide, for example. silicon oxide.

For example, during this step, cavity 30 is completely filled with layer 32. For example, layer 32 is deposited by chemical vapor deposition (CVD). By way of example, deposition of layer 32 is preceded by a step of oxidation of the surface of cavity 30, for example by a regenerative thermal oxidation process or RTP (Rapid Thermal Process).

At the end of this step, the openings 28 are for example also filled with the layer of insulating material 32. Thus, at the end of this step, the layer 20 is penetrated by pillars made of the insulating material of layer 32.

FIG. 11 is a schematic partial cross-sectional view of a structure obtained by planarizing the top face of the structure shown in FIG. 10.

For example, planarization of the structure is achieved by chemical mechanical polishing (CMP).

By way of example, this step reveals the top face of the nitride layer 24 without removing layers 22 and 24.

Although not shown, it can be envisaged that the insulating layers 22 and 24 are removed at the end of this step.

At the end of this step, in region a), an SOI-type substrate is thus obtained in and on which electronic components can be formed, for example. By way of example, transistors or radio-frequency switches of an electronic chip are formed in and on the silicon layer 20.

At the end of this step, the substrate thus formed comprises a region a) of the silicon-on-insulator type and a region b) of the silicon type. By way of example, at the end of this step, the top face of the substrate in region a) is aligned with the top face of the substrate in region b).

In the manufacturing process described above, the thickness of the insulating layer 32 is defined by the depth of the cavity 30, itself defined by the thickness of the sacrificial silicon-germanium layer 16. The thickness of the insulating layer 32 in the final SOI substrate can then be modulated and adapted according to the technologies of the electronic components formed on the substrate.

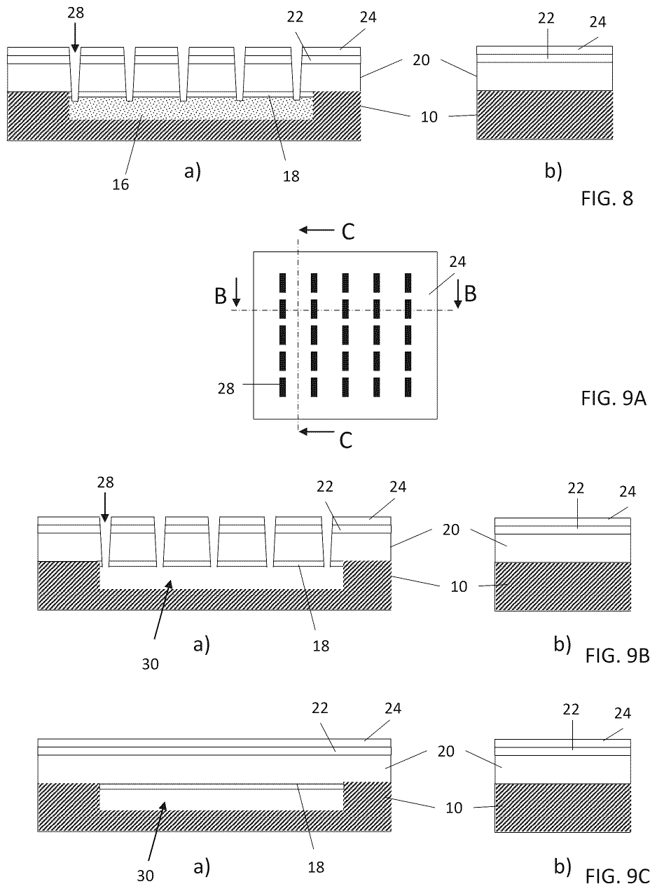

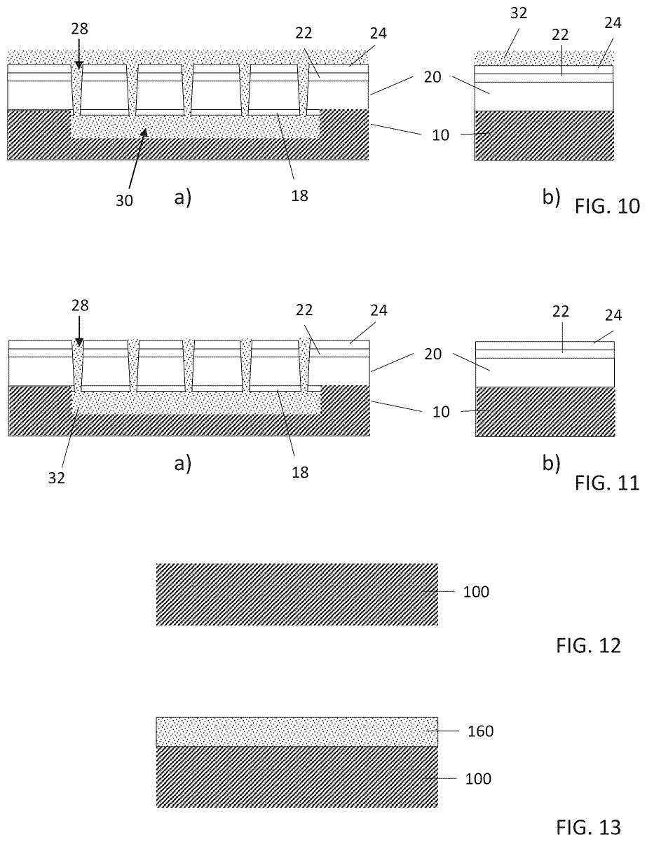

FIG. 12, FIG. 13, FIG. 14, FIG. 15, FIG. 16, FIG. 17 and FIG. 18 are cross-sectional views of structures obtained at the end of successive stages of an example of a process for manufacturing a substrate, of the silicon-on-insulator type, according to a second embodiment.

The second embodiment described below differs from the first embodiment, described in relation to FIGS. 1 to 11, in that the second embodiment does not include a step for removing part of the thickness of the substrate 10, and in that the silicon-germanium layer 16 is formed as a full sheet over the entire top face of the substrate 10.

FIG. 12 is a schematic partial cross-sectional view of a starting structure comprising a substrate 100 identical to the substrate 10 of the starting structure shown in FIG. 1

FIG. 13 is a schematic partial cross-sectional view of a structure obtained by forming a silicon-germanium layer 160 on the top surface of the starting structure shown in FIG. 12

This step is similar to that described with the deposition of layer 16 in relation to FIG. 4 except that, in FIG. 13, layer 160 is formed full sheet. In this way, layer 160 covers the entire surface of substrate 100. For example, the lower face of layer 160 is in contact with the upper face of substrate 100.

FIG. 14 is a schematic partial cross-sectional view of a structure obtained after a step to form a silicon layer 200 on the top face of the structure shown in FIG. 13. The 200 layer is, for example, similar to the layer 20 shown in FIG. 6.

This step is similar to that described in relation to FIG. 6, except that in FIG. 14, layer 200 is formed on, and for example in contact with, silicon-germanium layer 160. In this step, layer 200 is formed only in contact with silicon-germanium layer 160. By way of example, layer 200 is formed over the entire top face of layer 160.

FIG. 15 is a schematic partial cross-sectional view of a structure obtained by successively forming an insulating layer 220, another insulating layer 240 and a resin layer 260 on the upper face of the structure illustrated in FIG. 14.

Layers 220, 240 and 260 are respectively identical to layers 22, 24 and 26 described in relation to FIGS. 7A to 7C. This step is identical to that described in relation to FIGS. 7A and 7B.

By way of example, as described in relation to FIGS. 7A and 7B, the resin layer 260 undergoes a photolithography step so as to form patterns 270 thereon.

FIG. 16 is a schematic partial cross-sectional view of a structure obtained by etching the structure illustrated in FIG. 15, creating openings 280 through the structure into the silicon-germanium layer 160, and removing the resin layer 260 from the upper surface of the resulting structure.

These steps are identical to those described in relation to FIG. 8.

FIG. 17 is a schematic partial cross-sectional view of a structure obtained by removing part of the silicon-germanium layer 160 from the structure shown in FIG. 16, to create a cavity 300 between the substrate 100 and the silicon layer 200.

This step is similar to that described in relation to FIGS. 9A, 9B and 9C, except that the silicon-germanium layer 160 is not completely removed during this step.

During this step, the silicon-germanium layer 160 is only partially removed, so that the cavity 300 is bordered by a portion of the layer 160. This partial removal enables the structure to retain mechanical stability, and in particular enables layers 200, 220 and 240 to be held above cavity 300. The unetched portions of the silicon-germanium layer 160 act as a mechanical support for the overlying layers 200, 220 and 240.

By way of example, in addition to being retained on a peripheral portion of the substrate 100, layer 160 can also be retained locally in the form of pillars supporting the underside of layer 220.

For example, the location of the openings 280 and the duration of the etching step define the location of the parts of the layer 160 that remain after this etching step. Indeed, the parts of the layer 160 that remain are the parts of the layer 160 too far from an opening 28 to be etched during the etching step.

FIG. 18 is a schematic partial cross-sectional view of a structure obtained after an etching step, followed by a step of filling the cavity 300 with a layer 320 identical to the layer 32 described in relation to FIG. 10.

These steps are identical to those described in relation to FIGS. 10 and 11.

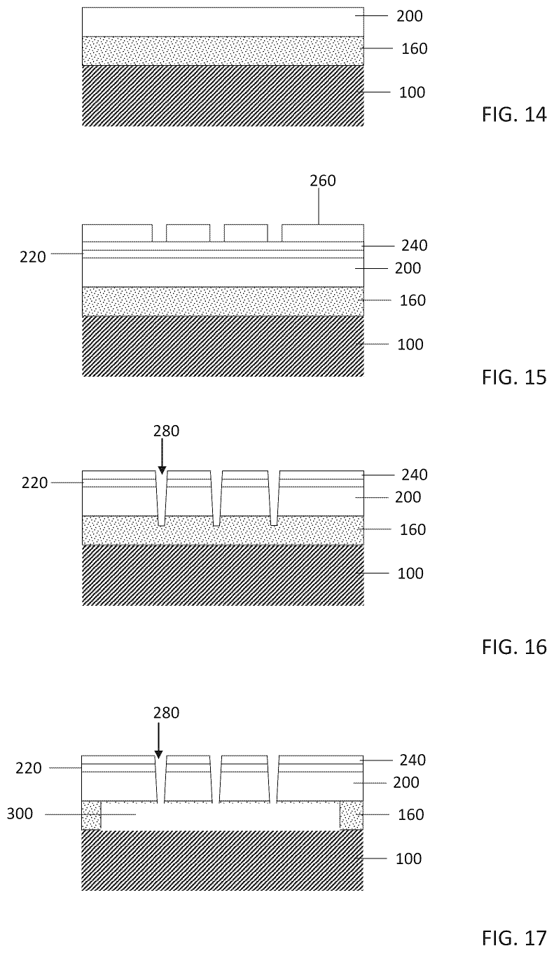

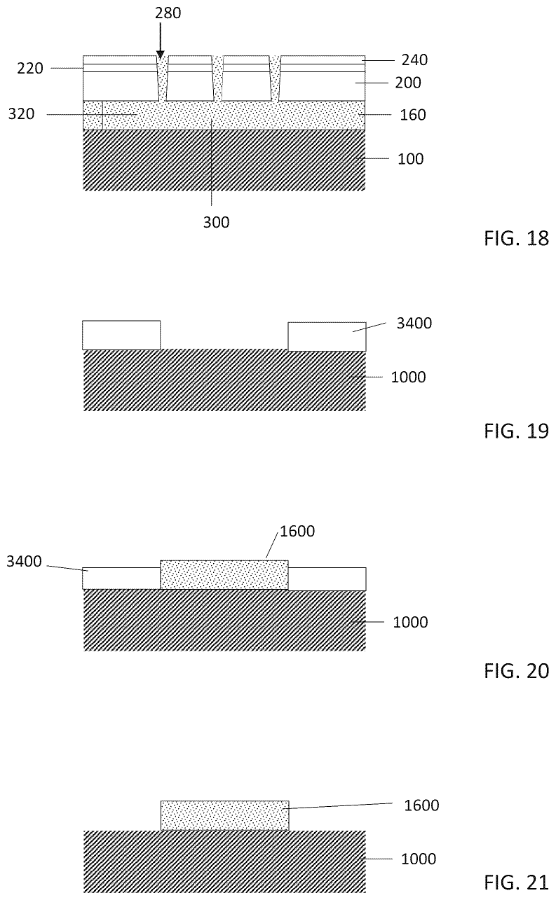

FIG. 19, FIG. 20, FIG. 21, FIG. 22, FIG. 23, FIG. 24 and FIG. 25 are cross-sectional views of structures obtained at the end of successive stages of a process for manufacturing a substrate, of the silicon-on-insulator type, according to a third embodiment.

The third embodiment described below differs from the second embodiment, described in relation to FIGS. 12 to 18, in that, in the third embodiment, the silicon germanium layer is formed on only part of the upper side of the substrate, the growth of the layer being guided by a dielectric layer.

FIG. 19 is a schematic partial cross-sectional view of a starting structure comprising a substrate 1000 identical to the substrate 100 of the starting structure illustrated in FIG. 12, the structure further comprising a dielectric layer 3400 on a portion of the upper face of the substrate 1000. By way of example, the dielectric layer 3400 is formed on a peripheral portion of the substrate 1000. By way of example, the dielectric layer 3400 is formed in contact with the top face of the substrate 1000.

FIG. 20 is a schematic partial cross-sectional view of a structure obtained by forming a silicon-germanium 1600 layer on the top surface of the starting structure shown in FIG. 19.

This step is similar to that described with the deposition of layer 160 in relation to FIG. 13, except that in FIG. 20, layer 1600 is not formed full sheet. In fact, layer 1600 is formed only in line with the exposed faces of substrate 1000. As a result, the silicon-germanium layer 1600, formed by silicon-selective epitaxy, has its growth “guided” by the dielectric layer 3400. For example, the lower face of layer 1600 is in contact with the upper face of substrate 1000.

FIG. 21 is a schematic partial cross-sectional view of a structure obtained by removing the dielectric layer 3400.

FIG. 22 is a schematic partial cross-sectional view of a structure obtained after a step of forming a silicon layer 2000 on the upper surface of the structure illustrated in FIG. 21. The layer 2000 is, for example, similar to the layer 200 shown in FIG. 14.

This step is similar to that described in relation to FIG. 14 except that, in FIG. 22, the layer 2000 is formed on, and for example in contact with, the silicon-germanium layer 1600 and on, and for example in contact with, the substrate 1000.

FIG. 23 is a schematic partial cross-sectional view of a structure obtained by successively forming an insulating layer 2200, another insulating layer 2400 and a resin layer 2600 on the upper face of the structure illustrated in FIG. 22, a step of etching the structure obtained by creating openings 2800 passing through the structure and opening into the silicon-germanium layer 1600 and a step of removing the resin layer 2600 from the upper face of the structure obtained.

Layers 2200, 2400 and 2600 are respectively identical to layers 220, 240 and 260 described in relation to FIG. 15.

By way of example, as described in relation to FIG. 16, the resin layer 2600 undergoes a photolithography step so as to form patterns 2700 thereon.

These steps are identical to those described in relation to FIGS. 15 and 16.

FIG. 24 is a schematic partial cross-sectional view of a structure obtained by removing part of the silicon-germanium layer 1600 from the structure shown in FIG. 23, to create a cavity 3000 between the substrate 1000 and the silicon layer 2000.

This step is similar to that described in relation to FIG. 17, except that in this step, the silicon-germanium layer 1600 is completely removed.

FIG. 25 is a schematic partial cross-sectional view of a structure obtained after an etching step followed by a step of filling the cavity 3000 with a layer 3200 identical to the layer 320 described in relation to FIG. 18.

This step is identical to that described in relation to FIG. 18.

In the third embodiment, the interface between layer 2000 and substrate 1000 is aligned with the interface between layer 3200 and substrate 1000.

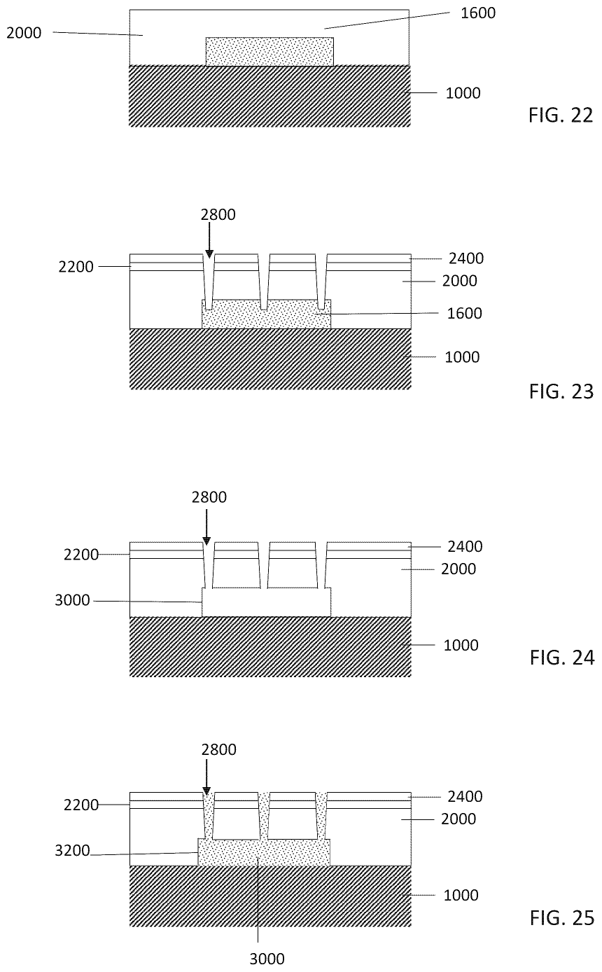

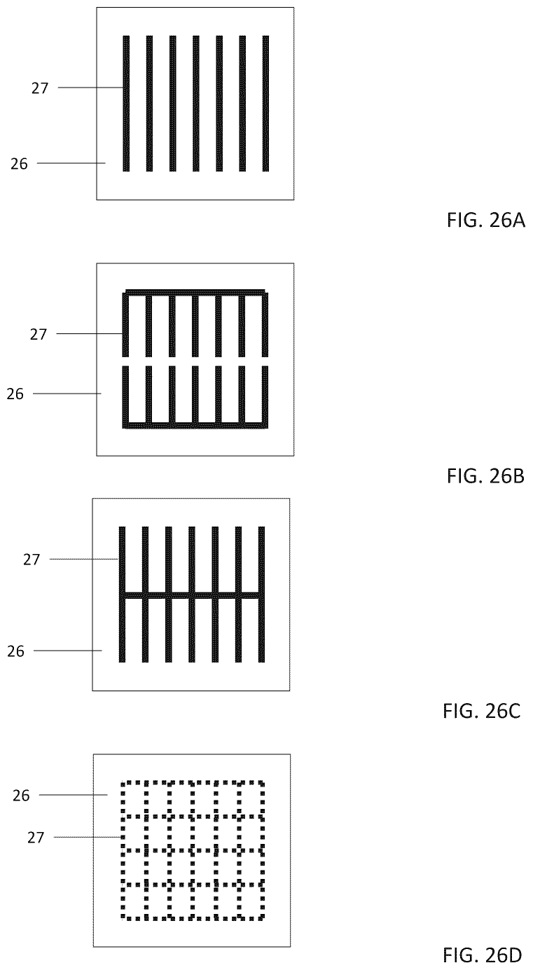

FIG. 26A, FIG. 26B, FIG. 26C and FIG. 26D are top views illustrating different versions of the structure shown in FIG. 7A.

More particularly, these figures illustrate further examples of patterns 27 formed in the resin layer 26 as an alternative to what has been shown in FIG. 7A.

By way of example, as shown in FIG. 26A, the patterns 27 in the resin layer 26 may correspond to straight, parallel lines.

By way of example, as shown in FIG. 26B, the patterns 27 in the resin layer 26 may correspond to two combs whose fingers, solid or dotted, face each other without touching.

By way of example, as shown in FIG. 26C, the patterns 27 in the resin layer 21 may correspond to a double comb comprising a handle and two rows of fingers, solid or dotted, aligned on either side of the handle.

By way of example, as shown in FIG. 26D, the patterns 27 in the resin layer 21 may correspond to a grid of vertical and horizontal dotted lines.

More generally, other patterns 27 not shown can be provided, with the provision that they do not mechanically isolate any portion of the resin layer 26. After the patterning stage, it is preferable that the layer 26 retain its mechanical cohesion, so that all portions of the layer 26 are integral with one another.

An advantage of the present embodiment is that it enables one or more SOI-type portions and one or more silicon substrate-type portions to be formed in and on the same substrate.

A further advantage of the present embodiment is that it enables an SOI-type substrate to be formed with a predefined insulator thickness.

Various embodiments and variants have been described. The person skilled in the art will understand that certain features of these various embodiments and variants could be combined, and other variants will become apparent to the person skilled in the art. In particular, although an embodiment has been described in which the silicon-germanium layer 16, 1600 is entirely removed from the cavity 30, 3000, a variant may be provided in which the silicon-germanium layer is intentionally retained in some of the portions of the cavity 30, 3000.

Finally, the practical implementation of the modes of realization and variants described is within the reach of person of the trade from the functional indications given above.

Method of manufacturing a silicon-on-insulator substrate is summarized as including the successive steps of: a) formation of a silicon-germanium layer (16; 160; 1600) on an upper surface of a silicon substrate (10; 100; 1000); b) formation of a silicon layer (20; 200; 2000) on an upper face of the silicon-germanium layer (16; 160; 1600); c) formation of at least one opening (28; 280; 2800) crossing the silicon layer (20; 200; 2000) and emerging into the silicon-germanium layer (16; 160; 1600); d) selective removal of at least part of the silicon-germanium layer (16; 160; 1600) through the openings (28; 280; 2800) to create a cavity between the silicon substrate (10; 100 ; 1000) and the silicon layer (20; 200; 2000), a cavity (30; 300; 3000); and e) filling the cavity (30; 300; 3000), through the opening (28; 280; 2800), with an insulating material (32; 320; 3200).

At the end of step e), the cavity (30; 300; 3000) is completely filled with the insulating material (32; 320; 3200).

At the end of step e), the cavity (30; 300; 3000) is partially filled with the insulating material (32; 320; 3200).

The silicon germanium layer (16; 160; 1600) is doped.

In step a), the silicon-germanium layer (16; 160; 1600) is formed by epitaxy.

In step b) the silicon layer (20; 200; 2000) is formed by epitaxy.

When filling the cavity (30; 300; 3000) in step e), the at least one opening (28; 280; 2800) crossing the silicon layer (20; 200; 2000) is filled with the insulating material (32; 320; 3200).

The method includes, prior to step a), a step of localized removal of part of the thickness of the silicon substrate (10), and, in step a), the silicon-germanium layer (16) is formed only in a cavity formed by said localized removal of part of the thickness of the silicon substrate (10).

In step d) the silicon-germanium layer (16) is completely or partially removed.

The method includes, between steps a) and b), a step of forming a silicon encapsulation layer (18) on the upper face of the silicon-germanium layer (16).

In step a), the silicon-germanium layer (160) is formed over the entire surface of the silicon substrate (100).

In step b), the silicon layer (200) is formed over the entire surface of the silicon-germanium layer (160) and is formed in contact therewith.

The method includes, prior to step a), a step of forming a dielectric layer (3400) on a portion of the substrate (1000), the silicon-germanium layer (16) being formed only outside the facing of the dielectric layer (3400).

A method of manufacturing an electronic chip in and on a silicon-on-insulator substrate obtained by the method is summarized as including a step of forming a transistor in and on the silicon layer (20; 200; 2000)

A silicon-on-insulator substrate is summarized as including, in a first region (a): a layer of insulating material (32; 320; 3200) on an upper face of a silicon substrate (10; 100; 1000); and a silicon layer (20; 200; 2000) on an upper face of the insulating material layer (32; 320; 3200), the silicon layer (20; 200; 2000) being crossed by at least one opening (28; 280; 2800).

Said at least one opening (28; 280; 2800) crossing the silicon layer (20; 200; 2000) is filled with said insulating material (32; 320; 3200).

In at least a second region (b), the silicon layer (20; 2000) lies directly on and in contact with the silicon substrate (10; 1000).

In which the lower surface of the silicon layer (2000), in the second region (b), is aligned with the lower surface of the layer of insulating material (3200), in the first region (a).

In which, in at least one second region (b), the silicon layer (200) is separated from the silicon substrate (100) by a silicon-germanium layer (160).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing a silicon-on-insulator substrate comprising:
forming a silicon-germanium layer on an upper surface of a silicon substrate;
forming a silicon layer on an upper face of the silicon-germanium layer;
forming an opening crossing the silicon layer and emerging into the silicon-germanium layer;
selectively removing at least part of the silicon-germanium layer through the opening creating a cavity between the silicon substrate and the silicon layer; and
filling the cavity, through the opening, with an insulating material.

2. The method of claim 1, wherein the cavity is completely filled with the insulating material.

3. The method of claim 1, wherein the cavity is partially filled with the insulating material.

4. The method according to claim 1, wherein the silicon germanium layer is doped.

5. The method according to claim 1, wherein the silicon-germanium layer is formed by epitaxy.

6. The method according to claim 1, wherein the silicon layer is formed by epitaxy.

7. The method according to claim 1, further comprising filling the opening with the insulating material.

8. The method according to claim 1, comprising forming a cavity in the silicon substrate by removing a localized portion of the thickness of the silicon substrate, and wherein the silicon-germanium layer is formed only in the cavity in the silicon substrate.

9. The method according to claim 8, in which the silicon-germanium layer is completely or partially removed.

10. The method according to claim 8, comprising forming a silicon encapsulation layer on the upper face of the silicon-germanium layer.

11. The method according to claim 1, wherein the silicon-germanium layer is formed over the entire surface of the silicon substrate.

12. The method according to claim 11, wherein the silicon layer is formed over the entire surface of the silicon-germanium layer and is formed in contact therewith.

13. The method according to claim 1, comprising forming a dielectric layer covering a portion of the silicon substrate, wherein the silicon-germanium layer is formed on the portion of the silicon substrate not covered by the dielectric layer.

14. A method of manufacturing an electronic chip, comprising, in the order:
forming a silicon-germanium layer on an upper surface of a silicon substrate;
forming a silicon layer on an upper face of the silicon-germanium layer;
forming an opening crossing the silicon layer and emerging into the silicon-germanium layer;
selectively removing at least part of the silicon-germanium layer through the opening creating a cavity between the silicon substrate and the silicon layer;
filling the cavity, through the opening, with an insulating material; and
forming a transistor in and on the silicon layer.

15. The method according to claim 14, comprising forming a radio-frequency switch in and on the silicon layer.

16. A silicon-on-insulator substrate comprising:
a silicon substrate;
a layer of insulating material on at least a first portion of the silicon substrate; and
a silicon layer on an upper face of the layer of insulating material,
wherein the silicon layer comprises an opening passing through the silicon layer.

17. The substrate of claim 16, wherein the opening is filled with an insulating material.

18. The substrate according to claim 16, wherein the silicon substrate comprises a second portion, wherein the silicon layer lies directly on and in contact with the second portion of the silicon substrate.

19. The substrate according to claim 18, in which the lower surface of the silicon layer on the second portion of the silicon substrate is aligned with the lower surface of the layer of insulating material on the first portion of the silicon substrate.

20. The substrate according to claim 16, wherein at least a portion of the silicon layer is separated from the silicon substrate by a silicon-germanium layer.
